(19) United States
(12) Patent Application Publication
(10) Pub. No.: US 2013/0141874 A1
(43) Pub. Date: Jun. 6, 2013

(54) SLIDING MECHANISM FOR SLIDING A DISPLAY MODULE RELATIVE TO A HOST MODULE AND PORTABLE ELECTRONIC DEVICE THEREWITH

(71) Applicant: Ching-Jeng Yu, New Taipei City (TW)

(72) Inventor: Ching-Jeng Yu, New Taipei City (TW)

(21) Appl. No.: 13/610,905

(22) Filed: Sep. 12, 2012

(30) Foreign Application Priority Data
Dec. 6, 2011 (TW) 100144804

(51) Int. Cl. H05K 7/02

(52) U.S. Cl. 361/729

(57) ABSTRACT

The present invention discloses a sliding mechanism for sliding a display module relative to a host module. The sliding mechanism includes a host module fixing component installed inside the host module, a display module fixing component connected to the host module fixing component, a sliding component disposed on a lateral side of the display module and installed on the display module fixing component in a slidable manner, and a roller set installed on the display module fixing component for guiding the sliding component to slide in a first direction relative to the display module fixing component, such that the display module can slide relative to the host module in the first direction.

### BACKGROUND OF THE INVENTION

1. Field of the Invention

The present invention relates to a sliding mechanism for sliding a display module relative to a host module and a portable electronic device therewith, and more particularly, to a sliding mechanism for sliding a display module relative to a host module by utilizing a roller set and a portable electronic device therewith.

2. Description of the Prior Art

A conventional tablet computer utilizes a touch panel for touch control. Since the tablet computer can not completely meet user's demands for convenience, a portable computer device combined with a notebook computer host with a keyboard and a touch panel arises. Conventionally, a hinge mechanism capable of pivoting relative to the notebook computer host is used for supporting the touch panel cooperatively with the notebook computer host. Additionally, a sliding rack is used for sliding the touch panel relative to the notebook computer host. However, the aforesaid conventional design results in an issue that the touch panel is incapable of smoothly sliding relative to the notebook computer host, such as an improper sliding resulting from rotation. Accordingly, it results in poor stability in use. In addition, the sliding rack and other sliding components are often made of metal materials for enhancing rigidity. When there are antennas installed on both sides of the notebook computer host, the metal sliding rack will result in shielding effect and further result in poor signal emitting and receiving of the antennas.

### SUMMARY OF THE INVENTION

The present invention provides a sliding mechanism for sliding a display module relative to a host module by utilizing a roller set and a portable electronic device therewith for solving above drawbacks.

According to the claimed invention, a sliding mechanism for sliding a display module relative to a host module includes a host module fixing component, a display module fixing component, a sliding component and a roller set. The host module fixing component is installed inside the host module. The display module fixing component is connected to the host module fixing component. The sliding component is disposed on a lateral side of the display module and installed on the display module fixing component in a slidable manner. The roller set is installed on the display module fixing component for guiding the sliding component to slide in a first direction relative to the display module fixing component, such that the display module slides relative to the host module in the first direction.

According to the claimed invention, the roller set includes at least one lateral roller contacting an inner lateral wall of the sliding component in a second direction, so as to constrain movement of the sliding component in the second direction, and the second direction is substantially perpendicular to the first direction.

According to the claimed invention, the roller set includes at least one longitudinal roller contacting an inner upper wall and an inner lower wall of the sliding component in a third direction, so as to constrain movement of the sliding component in the third direction, and the third direction is substantially perpendicular to the first direction.

According to the claimed invention, the roller set includes at least one trapezoid roller disposed inside a trapezoid opening on the display module, so as to constrain rotation of the display module relative to the host module in the first direction and in the second direction.

According to the claimed invention, the sliding mechanism further includes a plunger installed on the display module fixing component for being pressed by a protrusion of the display module.

According to the claimed invention, the sliding mechanism includes two display module fixing components respectively installed on two lateral sides of the display module, and the sliding mechanism further comprises a frame connected to the two display module fixing components.

According to the claimed invention, the sliding mechanism further includes a pivotal shaft connected to the host module fixing component and the display module fixing component for pivoting the display module fixing component relative to the host module fixing component.

According to the claimed invention, the sliding component is made of plastic materials.

According to the claimed invention, a portable electronic device includes a host module, a display module and a sliding mechanism. The display module is disposed on a side of the host module and slidable relative to the host module. The sliding mechanism is connected to the host module and the display module for sliding the display module relative to the host module and includes a host module fixing component, a display module fixing component, a sliding component and a roller set. The host module fixing component is installed inside the host module. The display module fixing component is connected to the host module fixing component. The sliding component is disposed on a lateral side of the display module and installed on the display module fixing component in a slidable manner. The roller set is installed on the display module fixing component for guiding the sliding component to slide in a first direction relative to the display module fixing component, such that the display module slides relative to the host module in the first direction.

According to the claimed invention, the sliding mechanism further includes a plunger installed on the display module fixing component, and the display module further includes at least one protrusion for pressing the plunger when the display module slides relative to the host module in a position where the protrusion corresponds the plunger. An inclined plane is respectively formed on two sides of the protrusion.

According to the claimed invention, an engaging slot is formed on the lateral side of the display module for engaging the sliding component.

In summary, the present invention utilizes the roller set for sliding the display module relative to the host module, so as to enhance stability in use. For example, the lateral roller, the longitudinal roller and the trapezoid roller are respectively used for constraining the movements in the directions different from the sliding direction, and further for preventing the display module from improperly sliding relative to the host module. Additionally, since the roller set of the present invention helps the display module to smoothly slide relative to the host module, there is no need to choose metal materials for the sliding component due to consideration of rigidity. For example, the present invention can choose materials other than metal materials, such as plastic materials, for the sliding component. Accordingly, when there are antennas installed on both sides of the portable electronic device, the present invention can prevent from shielding effect, so as to enhance quality of signal emitting and receiving of the antennas.

These and other objectives of the present invention will no doubt become obvious to those of ordinary skill in the art after reading the following detailed description of the embodiment that is illustrated in the various figures and drawings.

### BRIEF DESCRIPTION OF THE DRAWINGS

FIG. 1 and FIG. 2 are respectively schematic diagrams of a portable electronic device in different statuses according to an embodiment of the present invention.

FIG. 3 is an exploded diagram of a sliding mechanism according to the embodiment of the present invention.

FIG. 4 is an assembly diagram of the sliding mechanism according to the embodiment of the present invention.

FIG. 5 is a diagram illustrating that a roller set is installed on a display module fixing component according to the embodiment of the present invention.

FIG. 6 and FIG. 7 are respectively sectional diagrams of the sliding mechanism and the display module in different views according to the embodiment of the present invention.

### DETAILED DESCRIPTION

In the following detailed description of the embodiments, reference is made to the accompanying drawings which form a part hereof, and in which is shown by way of illustration specific embodiments in which the invention may be practiced. In this regard, directional terminology, such as “top,” “bottom,” etc., is used with reference to the orientation of the Figure(s) being described. The components of the present invention can be positioned in a number of different orientations. As such, the directional terminology is used for purposes of illustration and is in no way limiting. On the other hand, the drawings are only schematic and the sizes of components may be exaggerated for clarity. It is to be understood that other embodiments may be utilized and structural changes may be made without departing from the scope of the present invention. Also, it is to be understood that the phraseology and terminology used herein is for the purpose of description and should not be regarded as limiting. The use of “including,” “comprising,” or “having” and variations thereof herein is meant to encompass the items listed thereafter and equivalents thereof as well as additional items. Unless limited otherwise, the terms “connected,” and “installed” and variations thereof herein are used broadly and encompass direct and indirect connections and installations. Accordingly, the drawings and descriptions will be regarded as illustrative in nature and not as restrictive.

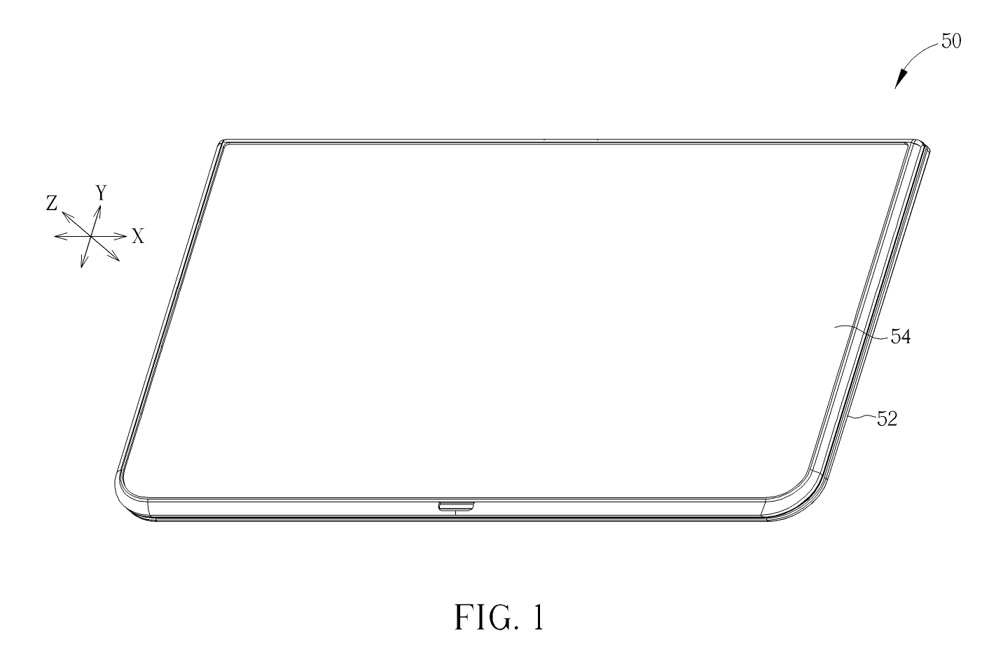

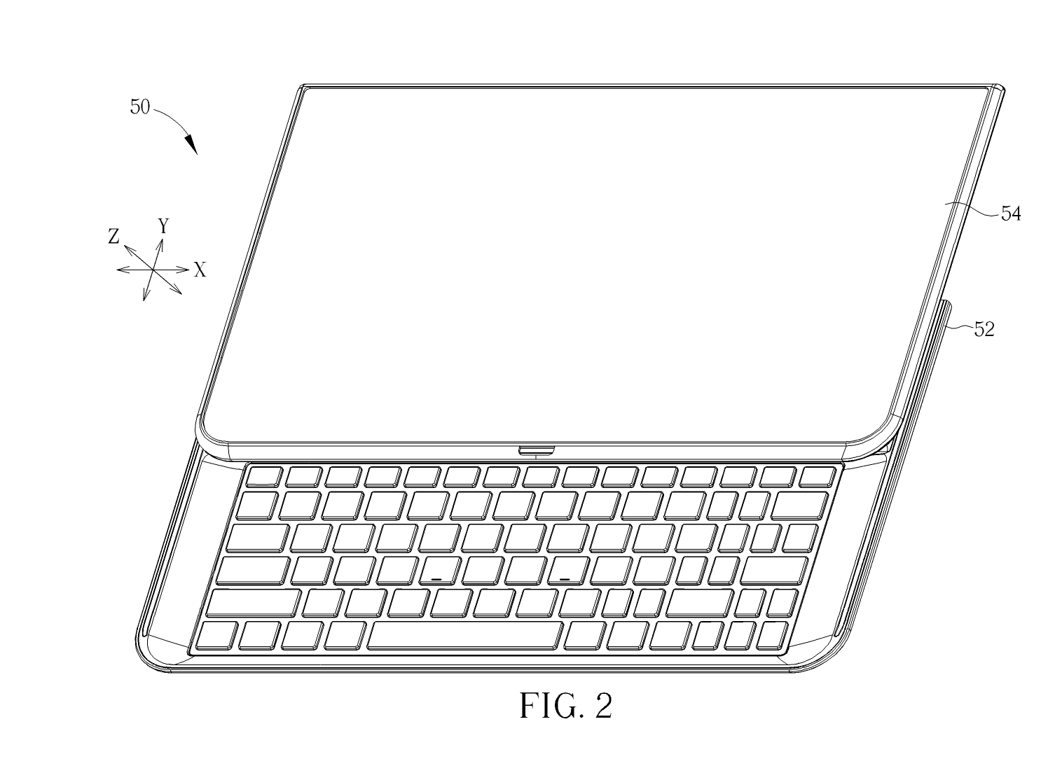

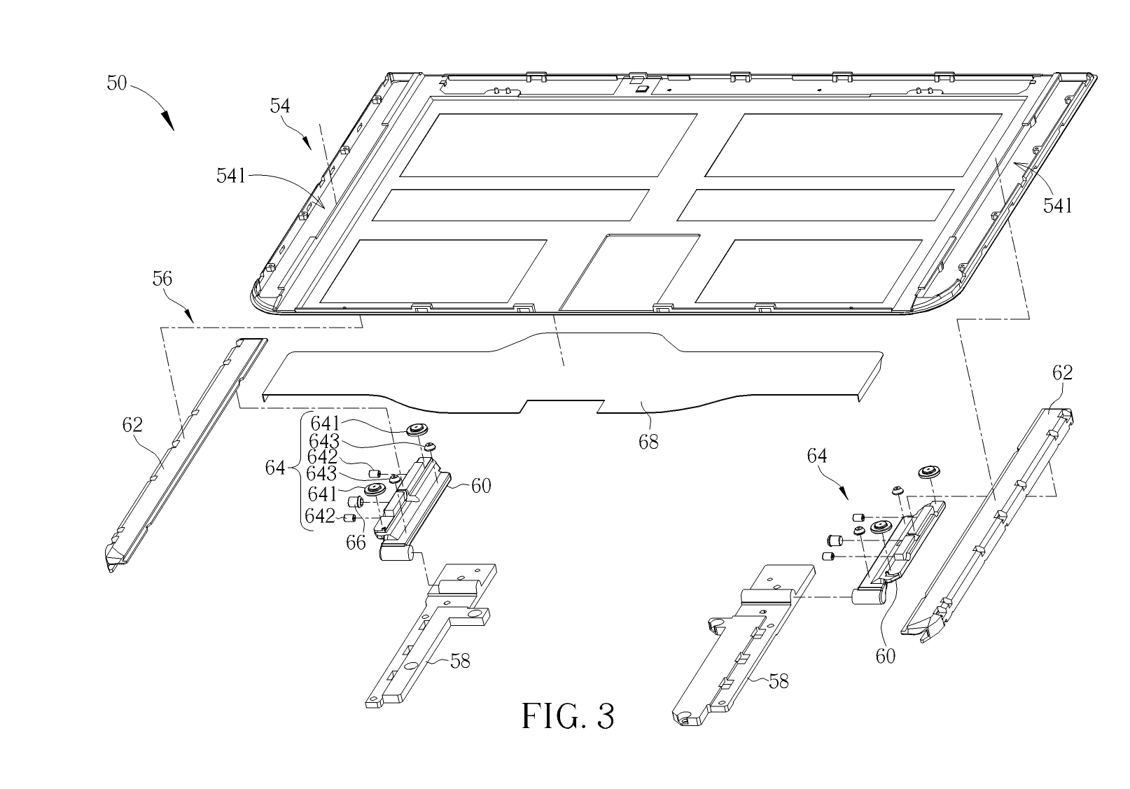

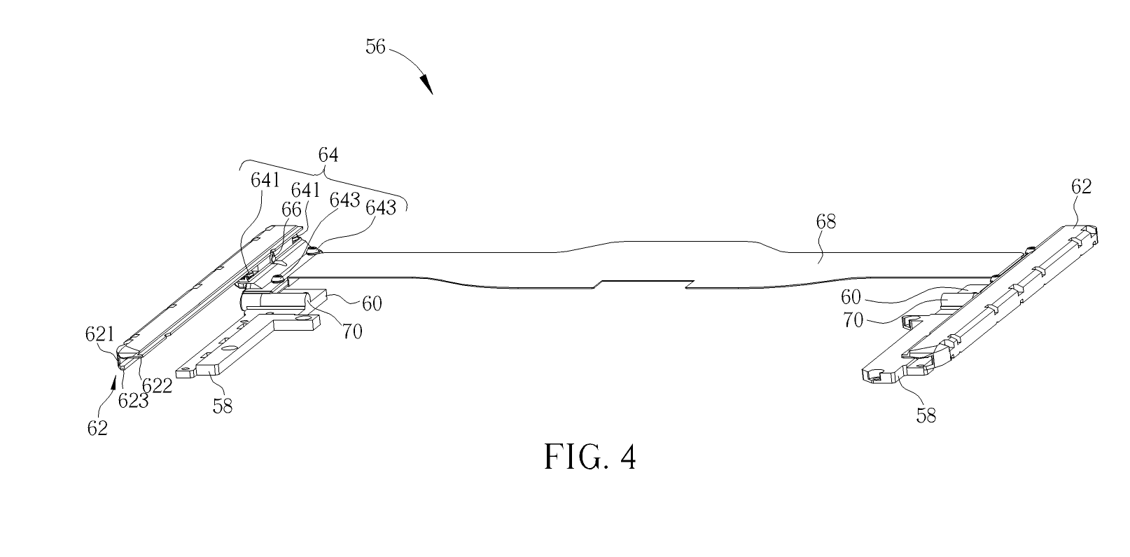

Please refer to FIG. 1 and FIG. 2. FIG. 1 and FIG. 2 are respectively schematic diagrams of a portable electronic device 50 in different statuses according to an embodiment of the present invention. In this embodiment, the portable electronic device 50 can be a portable computer device simultaneously possessing a notebook computer mode and a tablet computer mode. The portable electronic device 50 includes a host module 52. The host module 52 can be a computer host module with a keyboard or other input interfaces. The portable electronic device 50 further includes a display module 54 disposed on a side of the host module 52 and slidable relative to the host module 52. In this embodiment, the display module 54 can be a touch panel. In other words, the display module 54 can be used for touch control. Please refer to FIG. 1 to FIG. 4. FIG. 3 is an exploded diagram of a sliding mechanism 56 according to the embodiment of the present invention. FIG. 4 is an assembly diagram of the sliding mechanism 56 according to the embodiment of the present invention. In order to slide the display module 54 relative to the host module 52, the portable electronic device 50 further includes the sliding mechanism 56 connected to the host module 52 and the display module 54 for sliding the display module 54 relative to the host module 52. The sliding mechanism 56 includes at least one host module fixing component 58, at least one display module fixing component 60, at least one sliding component 62, at least one roller set 64, at least one plunger 66, a frame 68 and at least one pivotal shaft 70.

In this embodiment, the sliding mechanism 56 includes two host module fixing components 58, two display module fixing components 60, two sliding components 62, two roller sets 64, two plungers 66 and two pivotal shafts 70. The above-mentioned components are respectively disposed on two sides of the portable electronic device 50. Amounts and disposal positions of the above-mentioned components are not limited to those mentioned in this embodiment, and it depends on practical demands. Hereinafter, structures and principles are illustrated for the components on one side and omitted for the components on the other side since structures and principles of the components on the side are identical to those on the other side. The host module fixing component 58 is installed inside the host module 52, and the display module fixing component 60 is installed inside the display module 54 and connected to the host module fixing component 58. The frame 68 is connected to the two display module fixing components 60, so as to keep the two display module fixing components 60 to be located in the same horizontal position and further to ensure sliding stability of the display module 54. In this embodiment, the two display module fixing components 60 can be riveted to two ends of the frame 68, respectively. The pivotal shaft 70 is connected to the host module fixing component 58 and the display module fixing component 60 for pivoting the display module fixing component 60 relative to the host module fixing component 58. The sliding component 62 is disposed on a lateral side of the display module 54 and installed on the display module fixing component 60 in a slidable manner. An engaging slot 541 is formed on the lateral side of the display module 54 for engaging the sliding component 62. Additionally, the sliding component 62 can be made of plastic materials. When there are antennas installed on both sides of the portable electronic device 50, the present invention can prevent from shielding effect, so as to enhance quality of signal emitting and receiving of the antennas. Furthermore, the roller set 64 is installed on the display module fixing component 60 for guiding the sliding component 62 to slide in a first direction, i.e. a Y direction, relative to the display module fixing component 60, such that the display module 54 can smoothly slide relative to the host module 52 in the first direction, i.e. the Y direction.

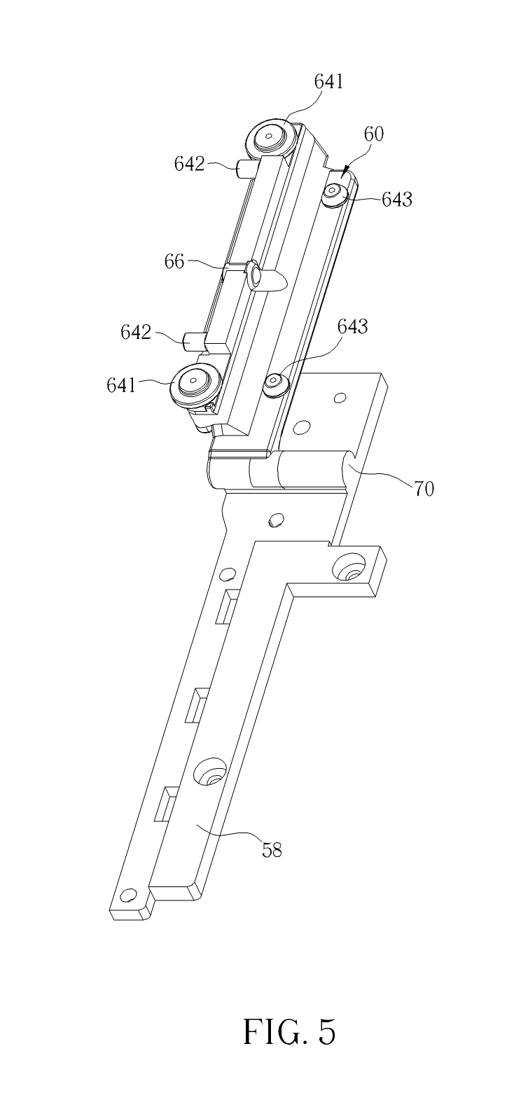

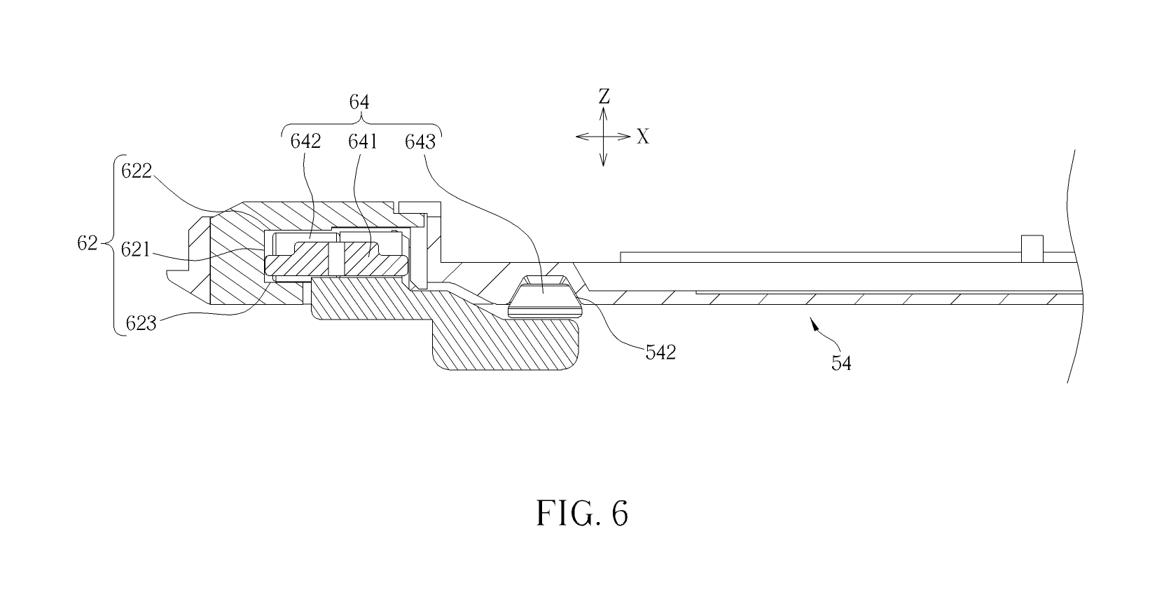

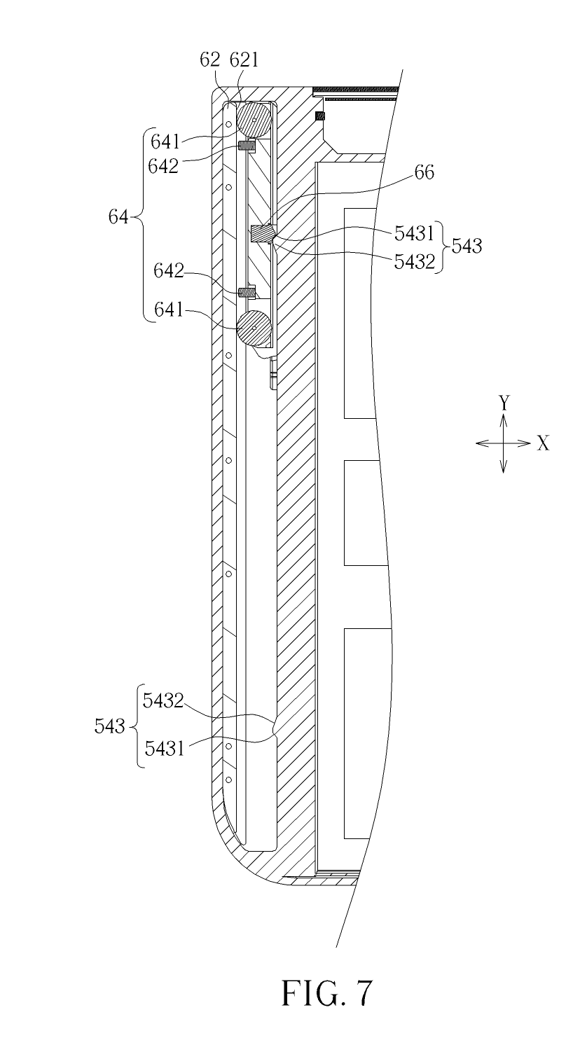

Please refer to FIG. 1 to FIG. 7. FIG. 5 is a diagram illustrating that the roller set 64 is installed on the display module fixing component 60 according to the embodiment of the present invention. FIG. 6 and FIG. 7 are respectively sectional diagrams of the sliding mechanism 56 and the display module 54 in different views according to the embodiment of the present invention. The roller set 64 includes at least one lateral roller 641, at least one longitudinal roller 642 and at least one trapezoid roller 643. The lateral roller 641 contacts an inner lateral wall 621 of the sliding component 62 in a second direction, i.e. an X direction, so as to constrain movement of the sliding component 62 in the second direction, i.e. the X direction. In this embodiment, the second direction, i.e. the X direction, can be substantially perpendicular to the first direction, i.e. the Y direction. The longitudinal roller 642 contacts an inner upper wall 622 and an inner lower wall 623 of the sliding component 62 in a third direction, i.e. a Z direction, so as to constrain movement of the sliding component 62 in the third direction, i.e. the Z direction. In this embodiment, the third direction, i.e. the Z direction, can be substantially perpendicular to the first direction, i.e. the Y direction. In other words, the first direction, i.e. the Y direction, the second direction, i.e. the X direction, and the third direction, i.e. the Z direction can be perpendicular to one another. The trapezoid roller 643 is disposed inside a trapezoid opening 542, such that a plane formed by the first direction, i.e. the Y direction and the second direction, i.e. the X direction can constrain rotation of the display module 54 relative to the host module 52. In other words, the present invention can prevent the display module 54 from improperly sliding relative to the host module 52. In this embodiment, each of the roller set 64 includes two lateral rollers 641, two longitudinal rollers 642 and two trapezoid rollers 643, and the two trapezoid rollers 643 are symmetric to each other for preventing the display module 54 from improperly sliding relative to the host module 52 in different directions. Amounts and disposal positions of the lateral roller 641, the longitudinal roller 642 and the trapezoid roller 643 of the roller set 64 are not limited to those mentioned in this embodiment, and it depends on practical demands.

In addition, the plunger 66 is installed on the host module fixing component 58. An end of the plunger 66 can be deformed inwardly as applying an external force, and the end of the plunger 66 can recover as removing the external force. As shown in FIG. 7, the display module 54 includes at least one protrusion 543. In this embodiment, two protrusions 543 are formed on a side of the display module 54. An amount and disposal positions of the protrusion 543 are not limited to those mentioned in this embodiment, and it depends on practical demands. When the display module 54 slides relative to the host module 52 in a position where the protrusion 543 corresponds the plunger 66, the protrusion 543 can press the plunger 66 for providing a user with a blocking feeling. Inclined planes 5431, 5432 are respectively formed on two sides of the protrusion 543. When the display module 54 slides relative to the host module 52, the inclined planes 5431, 5432 are used for guiding the plunger 66. In this embodiment, a slope of the inclined plane 5431 located on an outer side of the display module 54 can be greater than a slope of the inclined plane 5432 located on an inner side of the display module 54. In such a manner, when the display module 54 is about to be opened from a closed status or about to be closed from an opened status, it needs a greater force. When the plunger 66 passes an apex of the protrusion 543, it is easier to push the display module 54. Additionally, when the portable electronic device 50 is oriented vertically, the protrusion 543 can prevent the display module 54 from sliding downward relative to the host module 52 since the protrusion 543 is capable of stopping the plunger 66.

Compared to the prior art, the present invention utilizes the roller set for sliding the display module relative to the host module, so as to enhance stability in use. For example, the lateral roller, the longitudinal roller and the trapezoid roller are respectively used for constraining the movements in the directions different from the sliding direction, and further for preventing the display module from improperly sliding relative to the host module. Additionally, since the roller set of the present invention helps the display module to smoothly slide relative to the host module, there is no need to choose metal materials for the sliding component due to consideration of rigidity. For example, the present invention can choose materials other than metal materials, such as plastic materials, for the sliding component. Accordingly, when there are antennas installed on both sides of the portable electronic device, the present invention can prevent from shielding effect, so as to enhance quality of signal emitting and receiving of the antennas.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A sliding mechanism for sliding a display module relative to a host module, the sliding mechanism comprising:
a host module fixing component installed inside the host module;
a display module fixing component connected to the host module fixing component;
a sliding component disposed on a lateral side of the display module and installed on the display module fixing component in a slidable manner; and
a roller set installed on the display module fixing component for guiding the sliding component to slide in a first direction relative to the display module fixing component, such that the display module slides relative to the host module in the first direction.

2. The sliding mechanism of claim 1, wherein the roller set comprises at least one lateral roller contacting an inner lateral wall of the sliding component in a second direction, so as to constrain movement of the sliding component in the second direction, and the second direction is substantially perpendicular to the first direction.

3. The sliding mechanism of claim 1, wherein the roller set comprises at least one longitudinal roller contacting an inner upper wall and an inner lower wall of the sliding component in a third direction, so as to constrain movement of the sliding component in the third direction, and the third direction is substantially perpendicular to the first direction.

4. The sliding mechanism of claim 2, wherein the roller set comprises at least one trapezoid roller disposed inside a trapezoid opening on the display module, so as to constrain rotation of the display module relative to the host module in the first direction and in the second direction.

5. The sliding mechanism of claim 1, wherein the roller set comprises at least one trapezoid roller disposed inside a trapezoid opening on the display module, so as to constrain rotation of the display module relative to the host module in the first direction and in a second direction, and the second direction is substantially perpendicular to the first direction.

6. The sliding mechanism of claim 1, further comprising a plunger installed on the display module fixing component for being pressed by a protrusion of the display module.

7. The sliding mechanism of claim 1, wherein the sliding mechanism comprises two display module fixing components respectively installed on two lateral sides of the display module, and the sliding mechanism further comprises a frame connected to the two display module fixing components.

8. The sliding mechanism of claim 1, further comprising a pivotal shaft connected to the host module fixing component and the display module fixing component for pivoting the display module fixing component relative to the host module fixing component.

9. The sliding mechanism of claim 1, wherein the sliding component is made of plastic materials.

10. A portable electronic device, comprising:
a host module;
a display module disposed on a side of the host module and slidable relative to the host module; and
a sliding mechanism connected to the host module and the display module for sliding the display module relative to the host module, the sliding mechanism comprising:
a host module fixing component installed inside the host module;
a display module fixing component connected to the host module fixing component;
a sliding component disposed on a lateral side of the display module and installed on the display module fixing component in a slidable manner; and
a roller set installed on the display module fixing component for guiding the sliding component to slide in a first direction relative to the display module fixing component, such that the display module slides relative to the host module in the first direction.

11. The portable electronic device of claim 10, wherein the roller set comprises at least one lateral roller contacting an inner lateral wall of the sliding component in a second direction, so as to constrain movement of the sliding component in the second direction, and the second direction is substantially perpendicular to the first direction.

12. The portable electronic device of claim 10, wherein the roller set comprises at least one longitudinal roller contacting an inner upper wall and an inner lower wall of the sliding component in a third direction, so as to constrain movement of the sliding component in the third direction, and the third direction is substantially perpendicular to the first direction.

13. The portable electronic device of claim 11, wherein a trapezoid opening is formed on the display module, and the roller set comprises at least one trapezoid roller disposed inside the trapezoid opening on the display module, so as to constrain rotation of the display module relative to the host module in the first direction and in the second direction.

14. The portable electronic device of claim 10, wherein a trapezoid opening is formed on the display module, and the roller set comprises at least one trapezoid roller disposed inside the trapezoid opening on the display module, so as to constrain rotation of the display module relative to the host module in the first direction and in a second direction, and the second direction is substantially perpendicular to the first direction.

15. The portable electronic device of claim 10, wherein the sliding mechanism further comprises a plunger installed on the display module fixing component, and the display module further comprises at least one protrusion for pressing the plunger when the display module slides relative to the host module in a position where the protrusion corresponds the plunger.

16. The portable electronic device of claim 15, wherein an inclined plane is respectively formed on two sides of the protrusion.

17. The portable electronic device of claim 10, wherein the sliding mechanism further comprises a pivotal shaft connected to the host module fixing component and the display module fixing component for pivoting the display module fixing component relative to the host module fixing component.

18. The portable electronic device of claim 10, wherein the sliding mechanism comprises two display module fixing components respectively installed on two lateral sides of the display module, and the sliding mechanism further comprises a frame connected to the two display module fixing components.

19. The portable electronic device of claim 10, wherein the sliding component is made of plastic materials.

20. The portable electronic device of claim 10, wherein an engaging slot is formed on the lateral side of the display module for engaging the sliding component.
